(19) United States
(12) Patent Application Publication
(10) Pub. No.: US 2026/0026311 A1
(43) Pub. Date: Jan. 22, 2026

(54) SEMICONDUCTOR DEVICE INSPECTION METHOD

(71) Applicant: SAMSUNG ELECTRONICS CO., LTD., Suwon-si (KR)

(72) Inventors: Jinwoo LEE, Suwon-si (KR); In KWON, Suwon-si (KR); Hyeongcheol LEE, Suwon-si (KR); Jongcheon SUN, Suwon-si (KR); Su-Young LEE, Suwon-si (KR)

(73) Assignee: SAMSUNG ELECTRONICS CO., LTD., Suwon-si (KR)

(21) Appl. No.: 19/020,316

(22) Filed: Jan. 14, 2025

(30) Foreign Application Priority Data
Jul. 22, 2024 (KR) 10-2024-0096480

(51) Int. Cl. H01L 21/66; G01N 21/88; G01N 21/95

(52) U.S. Cl. CPC H01L 22/12; G01N 21/8806; G01N 21/9501

(57) ABSTRACT

A semiconductor device inspection method includes: selecting, for a semiconductor device including at least one layer, a target layer on which inspection and measurement are to be performed; selecting a material to fill a hole region formed inside the semiconductor device; conducting a simulation for an optical inspection and a measurement for the semiconductor device; selecting, based on the simulation, a wavelength band of light for the optical inspection and the measurement; and detecting, through the light at the selected wavelength, a lower portion of the semiconductor device and a defect of the semiconductor device. A refractive index of the material filling the inside of the hole region is greater than a refractive index of a molding layer surrounding the outside of the hole region.

### CROSS-REFERENCE TO RELATED APPLICATION

This application is based on and claims priority under 35 U.S.C. § 119 to Korean Patent Application No. 10-2024-0096480, filed on Jul. 22, 2024, in the Korean Intellectual Property Office, the disclosure of which is incorporated by reference herein in its entirety.

### BACKGROUND

### 1. Field

The embodiments relate to a semiconductor device inspection method, and more specifically, a method of inspecting a high aspect ratio contact (HARC) in semiconductor devices.

### 2. Description of Related Art

In semiconductor devices having a HARC, when measuring whether there is a defect inside a hole region forming a contact, there is an issue in that light performing an inspection stays only in a molding layer due to a difference in refractive indices between a molding layer surrounding the outside of the hole region and a material filling the inside of the hole region. Since the molding layer is not an inspection target, there is a need to develop inspection processes that allow the light performing the inspection to more accurately measure the inside and bottom of the hole region, which is the inspection target.

### SUMMARY

The embodiments provide a semiconductor device inspection method with improved reliability.

According to an aspect of the disclosure, a semiconductor device inspection method includes: selecting, for a semiconductor device including at least one layer, a target layer on which inspection and measurement are to be performed; selecting a material to fill a hole region formed inside the semiconductor device; conducting a simulation for an optical inspection and a measurement for the semiconductor device; selecting, based on the simulation, a wavelength band of light for the optical inspection and the measurement; and detecting, through the light at the selected wavelength, a lower portion of the semiconductor device and a defect of the semiconductor device, wherein a refractive index of the material filling the inside of the hole region is greater than a refractive index of a molding layer surrounding the outside of the hole region.

According to an aspect of the disclosure, a semiconductor device inspection method including: selecting an inspection and measurement target layer of a semiconductor device including a plurality of layers; selecting a material to be deposited in a hole region formed in the semiconductor device; conducting a simulation for an optical inspection and a measurement for the semiconductor device; selecting, based on the simulation, a wavelength band of light emitted from a light source for performing the inspection and measurement; and analyzing data corresponding to light incident on the hole region at the selected wavelength to detect a lower portion of the semiconductor device and a defect of the semiconductor device, wherein a refractive index of the material filling the inside of the hole region is greater than a refractive index of a molding layer surrounding the outside of the hole region, wherein the conducting of the simulation includes performing the optical inspection and measurement for each angle, and wherein an angle of the light source with respect to the hole region is determined according to data for light incident on the hole region.

According to an aspect of the disclosure, a semiconductor device inspection method of inspecting a semiconductor device including a plurality of hole regions, each hole region having a high aspect ratio contact (HARC), the method including: selecting an inspection and measurement target layer of the semiconductor device, wherein one or more depths of the plurality of hole regions differ from each other; selecting a material to be deposited in a hole region formed in the semiconductor device; conducting a simulation for an optical inspection and a measurement for the semiconductor device; selecting, based on the simulation, a wavelength band of light emitted from a light source for performing the inspection and measurement; and analyzing data corresponding to light incident on the hole region at the selected wavelength to detect a lower portion of the semiconductor device and a defect of the semiconductor device, wherein a refractive index of the material filling the inside of the hole region is greater than a refractive index of a molding layer surrounding the outside of the hole region, wherein the conducting of the simulation includes performing the optical inspection and measurement for each angle, by a measurement unit, wherein an angle of the light source with respect to the hole region is less than a critical angle determined by a refractive index of each of a material filling the hole region and a molding layer surrounding the outside of the hole region, wherein the molding layer comprises one of an oxide layer, a nitride layer, and a combination thereof, and wherein the material filling the hole region comprises amorphous silicon (a-Si).

### BRIEF DESCRIPTION OF THE DRAWINGS

Embodiments will be more clearly understood from the following detailed description taken in conjunction with the accompanying drawings in which:

FIG. 1 is a flowchart illustrating a semiconductor device inspection method according to one or more embodiments;

FIG. 2 is an equivalent circuit diagram of a memory cell array of a semiconductor device according to one or more embodiments;

FIG. 3 is a cross-sectional view of a semiconductor device according to one or more embodiments;

FIG. 4 is an enlarged perspective view of a region A of FIG. 3;

FIG. 5 is a plan view illustrating a semiconductor device in the vertical direction according to one or more embodiments;

FIG. 6 is a conceptual diagram illustrating a semiconductor device inspection method according to one or more embodiments;

FIG. 7 is a conceptual diagram illustrating a semiconductor device inspection method according to one or more embodiments;

FIG. 8 is cross-sectional views each illustrating an inspection simulation result when a hole region of a semiconductor device according to one or more embodiments is filled with air according to one or more embodiments;

FIG. 9 is cross-sectional views each illustrating an inspection simulation result when a hole region of a semiconductor device according to one or more embodiments is filled with a material including carbon according to one or more embodiments;

FIG. 10 is cross-sectional views each illustrating an inspection simulation result when a hole region of a semiconductor device according to one or more embodiments is filled with amorphous silicon;

FIG. 11 is cross-sectional views each illustrating an inspection simulation result for cross-sections in the vertical direction taken along line I-I′ of FIG. 10 according to one or more embodiments;

FIG. 12 is cross-sectional views each illustrating an inspection simulation result obtained while varying an angle of a light source when a hole region of a semiconductor device according to one or more embodiments is filled with amorphous silicon;

FIG. 13 is a perspective diagram schematically illustrating an electronic system including a semiconductor device according to one or more embodiments;

FIG. 14 is a perspective view schematically illustrating an electronic system including a semiconductor device according to one or more embodiments; and

FIG. 15 is a cross-sectional view schematically illustrating a semiconductor package including a semiconductor device according to one or more embodiments.

FIG. 16 is a block diagram of an example computer system, in accordance with embodiments of the present disclosure.

### DETAILED DESCRIPTION OF THE EMBODIMENTS

Since the present embodiments may be modified in various ways and may have various forms, some embodiments are illustrated in the drawings and described in detail. However, it is not intended to limit the present embodiments to the particular disclosed forms. In addition, embodiments described below are merely illustrative, and various modifications are possible from these embodiments.

The use of all examples or example terms is merely intended to describe the technical idea in detail and is not intended to be limiting in scope by such examples or example terms, unless being limited by the claims.

Hereinafter, unless otherwise specified, in the embodiments of the present disclosure, a vertical direction may be defined in a Z direction, and a first horizontal direction and a second horizontal direction may be defined in horizontal directions perpendicular to the Z direction, respectively. The first horizontal direction may be referred to as X, and the second horizontal direction may be referred to as Y. A vertical level may refer to a height level according to the vertical direction Z. A first horizontal direction and a horizontal width may refer to a length in the horizontal direction X and/or Y, and a vertical length may refer to a length in the vertical direction Z.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The specification uses the terms of degree including “substantially” or “about.” In one or more examples, when specifying that a parameter or range X may be substantially the same as parameter or range Y, the term “substantially” may be understood as X being within 10% of Y. In one or more examples, when specifying that a parameter or range is about X, the term “about” may be understood as being within 10% of X.

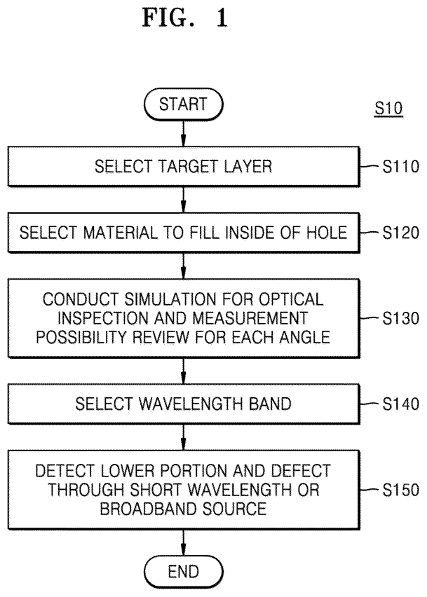

FIG. 1 is a flowchart illustrating a semiconductor device inspection method according to one or more embodiments.

Referring to FIG. 1, a semiconductor device to be inspected in the semiconductor device inspection method S10 according to the embodiments of the present disclosure may be a dynamic random-access memory (DRAM) or a NAND flash, or any other suitable semiconductor device known to one of ordinary skill in the art. The semiconductor device may include at least one layer. The semiconductor device inspection method S10 may include operation S110 of selecting a target layer to perform inspection and measurement. In one or examples, a processor or control unit that performs the method S10 may refer to information stored in a memory, where the information specifies a target layer for a particular type of semiconductor device. In one or more examples, the processor or control unit that performs the method S10 may control a camera or any other suitable sensor to detect the target layer.

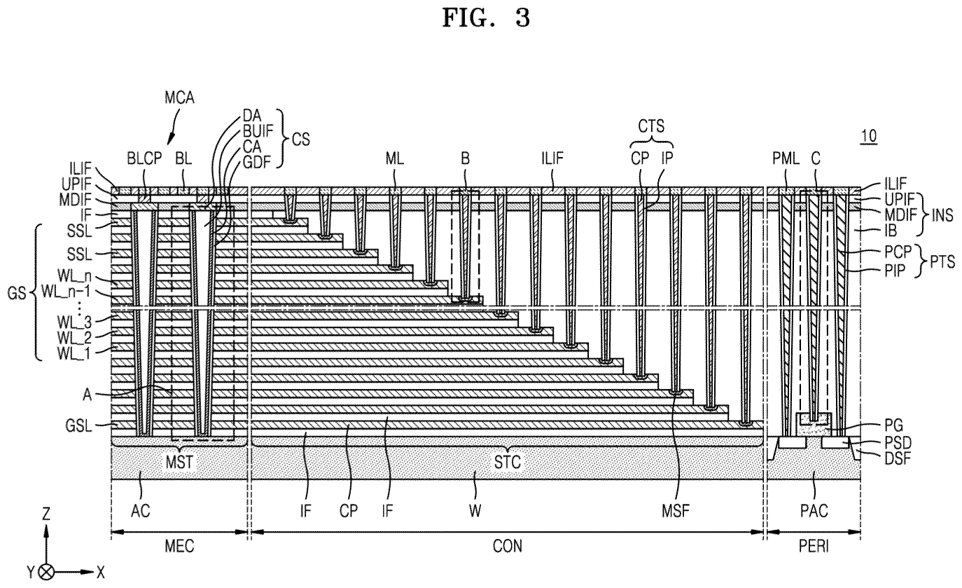

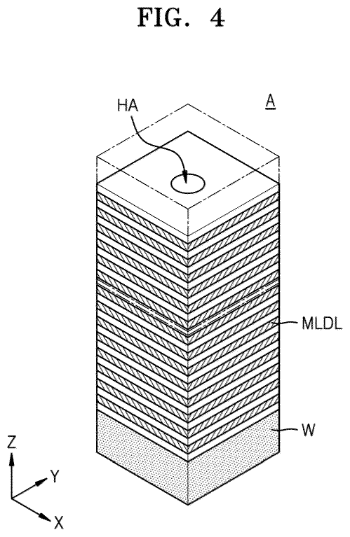

After performing operation S110, the semiconductor device inspection method S10 may include operation S120, which is an operation of selecting a material to fill a hole region HA (see FIG. 4) formed inside the semiconductor device. The hole region HA of FIG. 4 may be a region included in at least one of a contact structure CTS of FIG. 3, a channel structure CS of FIG. 3, and a peripheral contact structure PTS of FIG. 3. A material to fill the hole region HA of FIG. 4 may be selected in consideration of a refractive index. In one or more embodiments, a material to fill the hole region HA (FIG. 4) may be greater than a refractive index of a molding layer (MLDL of FIG. 4) surrounding a sidewall of the hole region HA (FIG. 4). By filling the hole region (HA of FIG. 4) with a material, the hole region (HA of FIG. 4) may serve as a waveguide through which light travels.

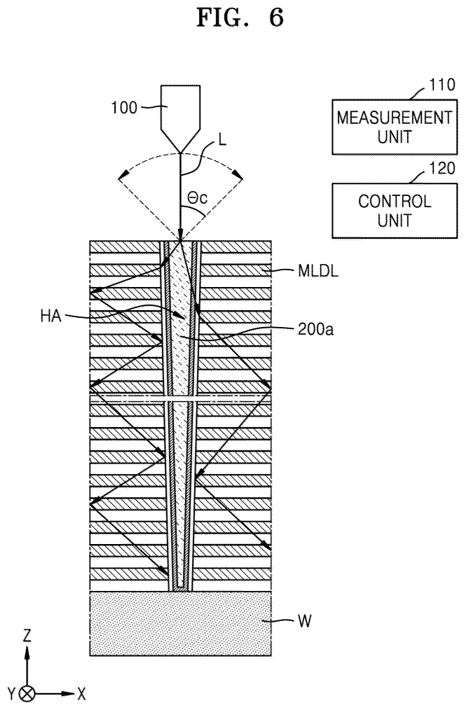

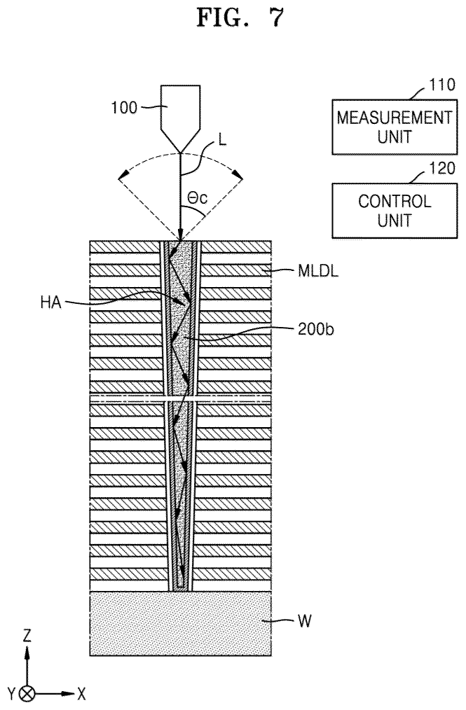

After performing operation S120, the semiconductor device inspection method S10 may include operation S130 of performing a simulation for an optical inspection and a measurement on the semiconductor device. In one or more examples, the optical inspection refers to a process performed by irradiating light emitted by a light source included in a semiconductor device inspection device to a semiconductor device. In one more examples, an optical measurement refers to a process of acquiring information inside the hole region (HA of FIG. 4) or information on the lowest surface of the hole region (HA of FIG. 4) by measuring the irradiated light through a measurement unit (110 of FIG. 6). In one or more embodiments, the light may be a laser. Since the depth and thickness of the hole region (HA of FIG. 4) may be different for each region or for each semiconductor device, operation S130 is an operation of performing a simulation for the optical inspection and the measurement by adjusting various wavelengths and angles of the light source in advance. When operation S130 is performed, the light source may rotate and irradiate light within a certain angle range instead of a single angle. For example, in operation S130 of performing the simulation, the optical inspection and measurement may be performed for each angle of a plurality of available angles. Details of the angle are described with reference to FIGS. 6 and 7.

After performing operation S130, the semiconductor device inspection method S10 may include operation S140, which is an operation of selecting a wavelength band of light for the optical inspection and measurement. The wavelength of light may be selected differently depending on the size of the hole region HA (see FIG. 4) in the vertical direction (e.g., direction of depth of hole). In one or more embodiments, the light may be a wavelength band in a visible or infrared region. The wavelength of light may be selected differently depending on the depth of the hole region HA of FIG. 4 or a material filling the hole region HA of FIG. 4. In one or more examples, the wavelength band of light may be selected based on the results of the simulation performed in operation S130. For example, based on the simulation conducted in operation S130, it may be determined a wavelength and/or angle of light in which a maximum amount of light is reflected in the hole region. Therefore, a wavelength and/or angle may be selected based on the results of the simulation.

After performing operation S140, the semiconductor device inspection method S10 may include operation S150 of detecting a lower portion and a defect of the semiconductor device through light. In one or more embodiments, the lower portion and the defect of a semiconductor device may correspond to the lower portion and the defect of a hole region HA in the semiconductor device (see FIG. 4). In one or more example, the lower portion of the semiconductor device may correspond to a bottom of the hole region HA, or a portion of the hole region HA below a midpoint of the hole region HA. A light source performing operation S150 may emit short-wavelength or broadband light. Operations S110 to S150 may be performed multiple times for one semiconductor device.

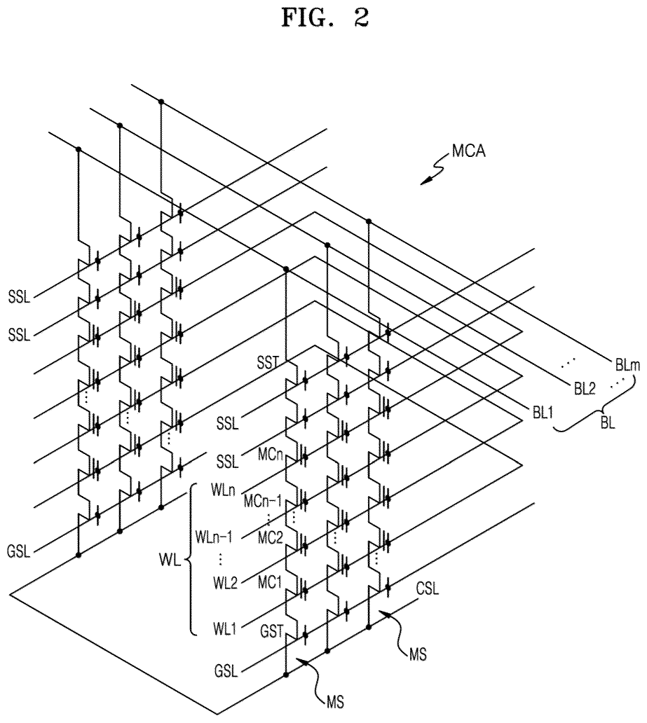

FIG. 2 is an equivalent circuit diagram of a memory cell array of a semiconductor device according to one or more embodiments.

Referring to FIG. 2, the memory cell array MCA may include a plurality of memory cell strings MS. The memory cell array MCA may include a plurality of bit lines BL (e.g., BL1, BL2, . . . , and BLm), a plurality of word lines WL (e.g., WL1, WL2, . . . , WLn-1, and WLn), at least one string selection line SSL, at least one ground selection line GSL, and a common source line CSL. The plurality of memory cell strings MS may be formed between the plurality of bit lines BL (e.g., BL1, BL2, . . . , and BLm) and the common source line CSL. FIG. 2 illustrates a case where each of the plurality of memory cell strings (MS) includes two string select lines SSL. As understood by one of ordinary skill in the art, the embodiments are not limited to these configurations. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn-1, and MCn. A drain region of the string selection transistor SST may be connected to the bit lines BL1, BL2, . . . , and BLm, and a source region of the ground selection transistor GST may be connected to the common source line CSL. The common source line CSL may be a region in which source regions of a plurality of ground selection transistors GST are connected in common.

The string selection transistor SST may be connected to the string selection line SSL, and the ground selection transistor GST may be connected to the ground selection line GSL. The plurality of memory cell transistors MC1, MC2, . . . , MCn-1, and MCn may each be connected to the plurality of word lines WL (e.g., WL1, WL2, . . . , WLn-1, and WLn).

FIG. 3 is a cross-sectional view of a semiconductor device according to one or more embodiments.

Referring to FIG. 3, the semiconductor device 10 may include a substrate W having a memory cell region MEC, a connection region CON, and a peripheral circuit region PERI. According to embodiments, an active region AC may be defined in the memory cell region MEC of the substrate W, and a peripheral active region PAC may be defined in the peripheral circuit region PERI.

According to embodiments, the peripheral active region PAC may be defined by a device isolation layer DSF. For example, the memory cell array MCA may be formed on the active region AC of the memory cell region MEC according to a manufacturing process of the semiconductor device 10 to be described later. For example, the connection region CON may be disposed adjacent to an edge side of the memory cell region MEC. The memory cell region MEC may be spaced apart from the peripheral circuit region PERI with the connection region CON therebetween. Although only the connection region CON disposed at one side of the memory cell region MEC is illustrated in FIG. 3, the connection region CON may be disposed at both sides of the memory cell region MEC in the first horizontal direction X.

According to embodiments, the device isolation layer DSF defining the peripheral active region PAC may be formed in the peripheral circuit region PERI of the substrate W. A peripheral transistor may be formed on the peripheral active region PAC. The peripheral transistor may constitute one or more of a plurality of circuits formed on the peripheral circuit region PERI. The peripheral transistor may be configured to be electrically connected to the memory cell region MEC through a wiring structure disposed in the connection region CON. The peripheral transistor may include a peripheral gate PG and a peripheral source/drain region PSD formed in the peripheral active region PAC on both sides of the peripheral gate PG. In embodiments, unit elements such as a resistor, a capacitor, or any other suitable unit element known to one of ordinary skill in the art may be further disposed on the peripheral circuit region PERI. According to embodiments, the substrate W may include Si, Ge, or SiGe.

According to embodiments, a plurality of insulating layers IF and a plurality of sacrificial layers may be alternately stacked one layer by one layer on the memory cell region MEC and the connection region CON of the substrate W. After the plurality of sacrificial layers are removed during the process, a ground selection line GSL and a conductive pad region CP may be formed on the position where the sacrificial layers have been removed. According to embodiments, the plurality of insulating layers IF may include silicon oxide, silicon nitride, or silicon oxynitride. According to embodiments, the plurality of sacrificial layers may include silicon nitride, silicon carbide, or polysilicon. For example, the plurality of insulating layers IF may include silicon oxide, and the plurality of sacrificial layers may include silicon nitride.

After forming an etching stop layer covering the uppermost insulating layer IF among the plurality of insulating layers IF, a portion of each of the plurality of insulating layers IF and the plurality of sacrificial layers may be removed from the connection region CON by a photolithography process, so that one end of each of the plurality of insulating layers IF and the plurality of sacrificial layers may gradually form a stepped structure STC having a smaller width in the horizontal direction as the distance from the substrate W increases. Thereafter, an insulating block IB covering the stepped structure STC and the peripheral transistor may be formed on the substrate W.

Then, a plurality of channel holes extending in the vertical direction (Z), while penetrating the plurality of insulating layers IF, and the plurality of sacrificial layers may be formed in the memory cell region MEC, and a gate dielectric layer GDF, a channel region CA, and a buried insulating layer BUIF may be formed in each of the plurality of channel holes to form a plurality of channel hole buried structures. In one or more examples, before the gate dielectric layer GDF, the channel region CA, and the buried insulating layer BUIF are formed inside each of the plurality of channel holes, operation S10 mentioned with reference to FIG. 1 may be performed. For example, the plurality of channel holes may correspond to one of hole regions inspected by operation S10 in FIG. 1. The plurality of channel holes may be defined as a region A.

According to embodiments, the gate dielectric layer GDF may include silicon oxide, hafnium oxide, aluminum oxide, zirconium oxide, tantalum oxide, silicon nitride, boron nitride, silicon boron nitride, impurity-doped polysilicon, a metal oxide, or a combination thereof. The metal oxide may include hafnium oxide, aluminum oxide, zirconium oxide, tantalum oxide, or a combination thereof. According to embodiments, the channel region CA may have a cylindrical shape. The channel region CA may include doped polysilicon or undoped polysilicon. According to embodiments, the buried insulating layer BUIF may fill an inner space of the channel region CA. The buried insulating layer BUIF may include an insulating material. For example, the buried insulating layer BUIF may include silicon oxide, silicon nitride, silicon oxynitride, or a combination thereof. In some embodiments, the buried insulating layer BUIF may be omitted, and in this case, the channel region CA may have a pillar structure without an inner space.

Then, an intermediate insulating layer MDIF covering the plurality of channel hole buried structures, stepped structures STC, and insulating blocks IB may be formed in the memory cell region MEC, the connection region CON, and the peripheral circuit region PERI, and a plurality of contact holes may be formed in the intermediate insulating layer MDIF to expose the top surfaces of the plurality of channel hole buried structures, and a plurality of drain regions DA may be formed in a plurality of contact holes to form the channel structure CS. The intermediate insulating layer MDIF may be formed to have a planarized top surface over the memory cell region MEC, the connection region CON, and the peripheral circuit region PERI. According to embodiments, the intermediate insulating layers MDIF may include silicon oxide, silicon nitride, or silicon oxynitride. According to embodiments, the drain region DA may include a doped polysilicon layer. A plurality of sacrificial layers may be substituted with a plurality of gate lines GL and a plurality of conductive pad regions CP.

In one or more examples, a plurality of word line cut trenches that penetrate the plurality of insulating layers IF and the plurality of sacrificial layers to expose the substrate W may be formed. The plurality of word line cut trenches may extend long in the first horizontal direction X and may be formed to cross the memory cell region MEC and the connection region CON.

According to embodiments, the plurality of sacrificial layers exposed through the plurality of word line cut trenches may be selectively removed to provide an empty space between every two of the plurality of insulating layers IF, and then a plurality of gate stacks GS may be formed by burying a conductive material in the empty space. According to embodiments, the plurality of gate stacks GS may include a metal, a metal silicide, an impurity-doped semiconductor, or a combination thereof. For example, each of the plurality of gate stacks GS may include a metal such as tungsten, nickel, cobalt, tantalum, etc., a metal silicide such as tungsten silicide, nickel silicide, cobalt silicide, tantalum silicide, doped polysilicon, or a combination thereof.

According to embodiments, the plurality of gate stacks GS may include a plurality of gate lines GL and a plurality of conductive pad regions CP integrally connected to the plurality of gate lines. According to embodiments, the plurality of conductive pad regions CP may form a stepped structure STC on the connection region CON. According to embodiments, a portion of the gate stack GS disposed on the memory cell region MEC may constitute a memory stack MST. For example, the memory stack MST may include 48 to 128 gate lines stacked in the vertical direction Z, but is not limited thereto. The plurality of gate lines included in the gate stack GS may be disposed on the memory cell region MEC to extend in the horizontal direction parallel to the top surface of the substrate W, and may overlap each other in the vertical direction Z. According to embodiments, the plurality of gate lines may include the plurality of word lines WL e.g., WL1, WL2, . . . , WLn-1, and WLn), at least one ground selection line GSL, and at least one string selection line SSL. Although FIG. 3 illustrates a case in which the plurality of gate lines include two ground selection lines GSL and two string selection lines SSL, embodiments are not limited thereto.

After an upper insulating layer UPIF is formed, a plurality of bit line contact pads BLCP penetrating the upper insulating layer UPIF and connected to the plurality of channel structures CS in the memory cell region MEC may be formed. The insulating block IB, the intermediate insulating layer MDIF, and the upper insulating layer UPIF may constitute an insulating structure INS. According to embodiments, the plurality of bit line contact pads BLCP may be insulated from each other by the upper insulating layer UPIF. The plurality of bit line contact pads BLCP may include metal, metal nitride, or a combination thereof. According to embodiments, each of the upper insulating layers UPIF may include an oxide layer, a nitride layer, or a combination thereof.

A metal silicide layer MSF may be formed on a surface of the conductive pad region CP exposed through each of the plurality of first contact holes on the connection region CON, and a contact structure CTS may be formed on the metal silicide layer MSF in each of the plurality of first contact holes. Before or after the contact structure CTS is formed inside each of the plurality of first contact holes, the operation S10 mentioned with reference to FIG. 1 may be performed. That is, the plurality of first contact holes may correspond to one of hole regions inspected by operation S10 in FIG. 1. The plurality of first contact holes may be defined as a region B.

For example, the contact structure CTS may include a contact plug CTP extending in the vertical direction Z and being in contact with the metal silicide layer MSF, and an insulating plug IP surrounding the contact plug CTP. In addition, a peripheral contact structure PTS may be formed by sequentially forming a peripheral insulating plug PIP and a peripheral contact plug PCP in each of a plurality of second contact holes on the peripheral circuit region PERI. Before or after the peripheral contact structure PTS is formed inside each of the plurality of first contact holes, the operation S10 mentioned with reference to FIG. 1 may be performed. That is, the plurality of second contact holes may correspond to one of hole regions inspected by operation S10 in FIG. 1. The plurality of second contact holes may be defined as a region C.

According to embodiments, each of the insulating plug IP and the peripheral insulating plug PIP may include a silicon nitride layer, a silicon oxide layer, or a combination thereof. According to embodiments, each of the contact plug CTP and the peripheral contact plug PCP may include tungsten, titanium, tantalum, copper, aluminum, titanium nitride, tantalum nitride, tungsten nitride, or a combination thereof. According to embodiments, the metal silicide layer MSF may include WSi, WSiN, WSiO, or a combination thereof. In one or more examples, the terms “WSi”, “WSiN”, and “WSiO” used in this specification mean materials composed of the elements included in each term, and are not chemical formulas representing stoichiometric relationships.

In one or more embodiments, after forming an interlayer insulating layer ILIF covering the resultant on the memory cell region MEC, the connection region CON, and the peripheral circuit region PERI, a plurality of bit lines BL, a plurality of wiring layers ML, and a plurality of peripheral wiring layers PML penetrating some regions of the interlayer insulating layer ILIF may be formed.

According to embodiments, the drain region DA of each of the plurality of channel structures CS may be connected to one corresponding bit line BL among the plurality of bit lines BL through a bit line contact pad BLCP. According to embodiments, the plurality of bit lines BLs may be insulated from each other by the interlayer insulating layer ILIF. According to embodiments, the plurality of bit lines BL may include metal, metal nitride, or a combination thereof. For example, the plurality of bit lines BL may include tungsten, titanium, tantalum, copper, aluminum, titanium nitride, tantalum nitride, tungsten nitride, or a combination thereof. According to embodiments, each of the interlayer insulating layers ILIF may include an oxide layer, a nitride layer, or a combination thereof.

According to embodiments, the plurality of wiring layers ML may be formed at the same level as the plurality of bit lines BL disposed on the memory cell region MEC. According to embodiments, each of the plurality of wiring layers ML may be connected to the contact plug CTP of each contact structure CTS. According to embodiments, each of the plurality of wiring layers ML may be configured to be electrically connected to one conductive pad region CP selected from among the plurality of conductive pad regions CP through one contact plug CTP selected from among the plurality of contact plugs CTP. According to embodiments, the plurality of wiring layers ML may not include a portion vertically overlapping the memory stack MST. According to embodiments, the plurality of wiring layers ML may be insulated from each other by the interlayer insulating layer ILIF on the connection region CON. According to embodiments, the plurality of wiring layers ML may include tungsten, titanium, tantalum, copper, aluminum, titanium nitride, tantalum nitride, tungsten nitride, or a combination thereof.

According to embodiments, a plurality of peripheral wiring layers PML may extend long in the horizontal direction at the same level as the level of the plurality of wiring layers ML formed in the connection region CON. According to embodiments, each of the plurality of peripheral wiring layers PML may be connected to any one of a peripheral gate PG and a peripheral source/drain region PSD through any one of the plurality of peripheral contact plugs CTP. At least some of the plurality of peripheral wiring layers PML may be configured to be connected to other circuits or wirings disposed on the peripheral circuit region PERI. The plurality of peripheral wiring layers PML may be insulated from each other by the interlayer insulating layer ILIF. According to embodiments, each of the plurality of peripheral wiring layers PML may include tungsten, titanium, tantalum, copper, aluminum, titanium nitride, tantalum nitride, tungsten nitride, or a combination thereof.

Hereinafter, the process of performing inspection and measurement on the region A is described in detail. However, as mentioned above, operation S10 of FIG. 1 may be performed not only for region A but also for regions B and C, and may be extended to a case where a semiconductor device is a DRAM.

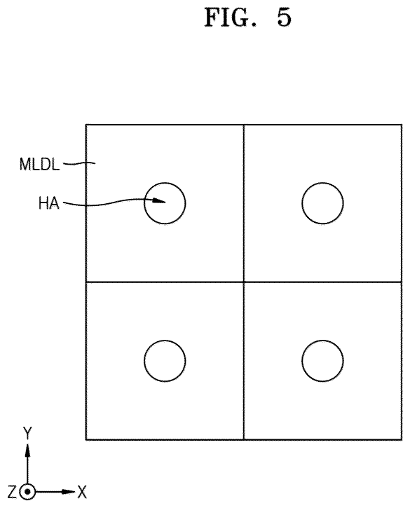

FIG. 4 is an enlarged perspective view of a region A of FIG. 3. FIG. 5 is a plan view illustrating a semiconductor device in the vertical direction according to one or more embodiments.

Reference is made to FIGS. 4 and 5 along with FIGS. 1 to 3. A molding layer MLDL may be formed on a substrate W. The molding layer MLDL may be one of the gate stack GS, the stepped structure STC, and the insulating block IB of FIG. 3, but is not limited thereto and may surround the first contact holes, the second contact holes, or the channel structure CS. For example, as illustrated in FIG. 4, which illustrates an enlargement of region A, the molding layer MLDL may correspond to a plurality of gate stacks GS.

A hole region HA may be formed inside the molding layer MLDL. When viewed vertically, a cross-section of the hole region HA may have a circular shape, but the shape of the cross-section of the hole region HA may not be limited thereto, and may have an oval shape, a quadrangular shape, or any other suitable shape known to one of ordinary skill in the art. The length of the molding layer MLDL in the vertical direction may vary according to the number of stages in which the gate stack is deposited. In one or more embodiments, if the thickness of the ground selection line GSL is about 15 nm, the thickness of the insulating layer IF is about 25 nm, and 75 stages of the ground selection line GSL and the insulating layer IF are stacked, the length of the molding layer MLDL in the vertical direction may be 3 μm. In one or more embodiments, the length of each side of the molding layer MLDL in the horizontal direction may be 0.5 μm to 1.5 μm.

In one or more embodiments, the diameter of the hole region HA may be 100 nm to 500 nm. In one or more embodiments, the diameter of the hole region HA may be shorter than the length of a wavelength of light (L in FIG. 6) emitted from a light source (100 in FIG. 6).

The molding layer MLDL may be a region forming the periphery of a high aspect ratio contact structure (HARC) having a high vertical height compared to a cross-sectional area in the horizontal direction. For example, the hole region HA may correspond to a contact region included in the high aspect ratio contact structure HARC. As understood by one of ordinary skill in the art HARC etching is a process for the fabrication of advanced semiconductor devices, especially for 3D NAND flash memory. HARC etching involves creating deep and narrow holes in a multilayer stack of materials, which requires precise control of the etch profile, uniformity, and selectivity.

When viewed from an axis in the vertical direction, a plurality of molding layers MLDL may be disposed. The plurality of molding layers MLDL may be in contact with each other. Although it is shown that the hole region HA is formed in each molding layer MLDL, the hole region HA may not be formed in the molding layer MLDL.

FIG. 6 is a conceptual diagram illustrating a semiconductor device inspection method according to one or more embodiments. FIG. 7 is a conceptual diagram illustrating a semiconductor device inspection method according to another embodiment.

Description is made with reference to FIGS. 6 and 7 together with FIGS. 1 to 5. An inspection apparatus for performing the semiconductor device inspection method S10 of FIG. 1 may include a light source 100, a measurement unit 110, and a control unit 120. The light source 100 may emit light L, and the measurement unit 110 may measure information contained in the light L emitted from the light source 100. Based on the data measured by the measurement unit 110, the control unit 120 may control the light source 100 to rotate or control the wavelength band of light L emitted from the light source. In one or more examples, the light source may be rotated around an axis passing through the light source and the hole region HA.

As shown in FIG. 6, the inside of the hole region HA may be filled with a first material 200a in one or more embodiments. As shown in FIG. 7, the inside of the hole region HA may be filled with a second material 200b in another embodiment. The first material 200a and the second material 200b may have different refractive indices.

The refractive index of the first material 200a may be less than that of the molding layer MLDL. When the hole region HA is deposited with the first material 200a and the light source 100 irradiates the light L with respect to the hole region HA, the light L may not proceed inside the hole region HA, but may proceed only inside the molding layer MLDL after being refracted to the molding layer MLDL. Some light may be refracted into the hole region HA from the molding layer MLDL, but when the incident angle is greater than the critical angle determined in accordance with the molding layer MLDL and the first material 200a, the light L may proceed only inside the molding layer MLDL. For example, the critical angle may be determined based on the type of materials used for the molding layer MLDL and the first material 200a.

The light source 100 of the embodiments of the present disclosure is used to determine whether there is a defect located on the inside of the hole region HA and the bottom surface of the hole region HA, and when the refractive index of the first material 200a is less than the refractive index of the molding layer MLDL as shown in FIG. 6, there is a limitation in that only the molding layer MLDL, which is not a target to be inspected and measured, is inspected and measured.

Accordingly, according to the embodiments of the present disclosure, the inside of the hole region HA is deposited with the second material 200b in order to more accurately grasp the inside of the hole region HA, which is a substantial target to be inspected and measured by the light L. The refractive index of the second material 200b may be higher than that of the first material 200a. In one or more examples, the refractive index of the second material 200b may be higher than the refractive index of the molding layer MLDL.

The control unit 120 may adjust an angle at which the light source 100 irradiates light L. The magnitude of the angle at which the optical inspection and measurement are performed may be less than the magnitude of the critical angle θc determined by the refractive index of each of the second material 200b and the molding layer MLDL surrounding the outside of the hole region HA. The light source 100 emitting the light L may emit the broadband light L as well as the short wavelength light. In one or more examples, the critical angle is set based on the surface where the second material 200b and the molding layer MLDL are in contact, but the critical angle θc in the embodiments of the present disclosure means the scanning angle of light L at the light source 100, which is calculated to be refracted or reflected from the surface where the second material 200b and the molding layer MLDL are in contact. In one or more examples, the angle of the light source 100 with respect to the hole region HA may be determined by the control unit 120 according to data on the light L incident on the hole region HA.

When the refractive index of the second material 200b is greater than the refractive index of the molding layer MLDL, and the incident angle of the light L incident from the light source 100 is less than the size of the critical angle θc determined by the refractive index of each of the second material 200b and the molding layer MLDL surrounding the outside of the hole region HA, the light L may proceed inside the hole region HA including the second material 200b. For example, when these conditions are satisfied, the light L is completely or substantially reflected inside the hole region HA and may travel to the bottom of the hole region HA.

As described above, the hole region HA may be not only region A, but also region B and region C. The lengths of the regions A, B, and C in the vertical direction Z may be different from each other. For example, the region B corresponds to a stepped structure STC, and thus the lengths of the contact structures in the vertical direction may be different. Conventionally, in order to accurately measure the hole region HA, there was a limitation that the focus of the light source 100 had to be calculated and then designated as the bottom point of the hole region HA. However, when the light L travels to the floor when there is total or substantial reflection inside the hole region HA as in the embodiments of the present disclosure, for example, when the hole region HA serves as a waveguide as a type of optical path, there is a technical feature that does not require the focus of the light source 100 to be designated to the bottom point of the hole region HA every time. In one or more embodiments, the focus of the light source 100 emitting light L may be located not only in the bottom region of the hole region HA, but also inside the hole region HA, and furthermore, may be located outside the hole region HA.

In one or more embodiments, the first material 200a may be simple air. In one or more embodiments, the first material 200a may be a material including carbon. In one or more embodiments, the second material 200b may be amorphous silicon (a-Si). In one or more embodiments, the molding layer MLDL may be one of an oxide layer, a nitride layer, and a combination thereof.

The wavelength band of the light L may be greater than the diameter of the hole region HA, and in one or more embodiments, the wavelength band of the light L may be about 1000 nanometers (nm) to about 1550 nm. The light L may be emitted in a plurality of modes.

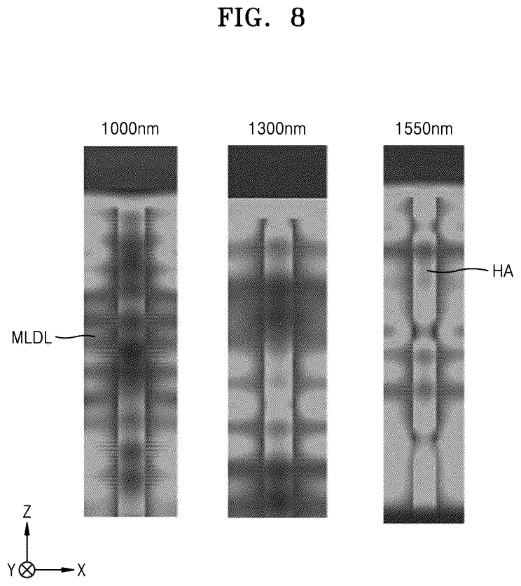

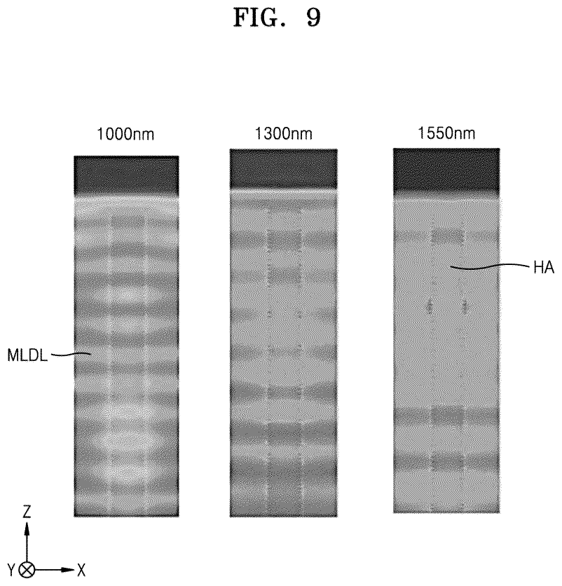

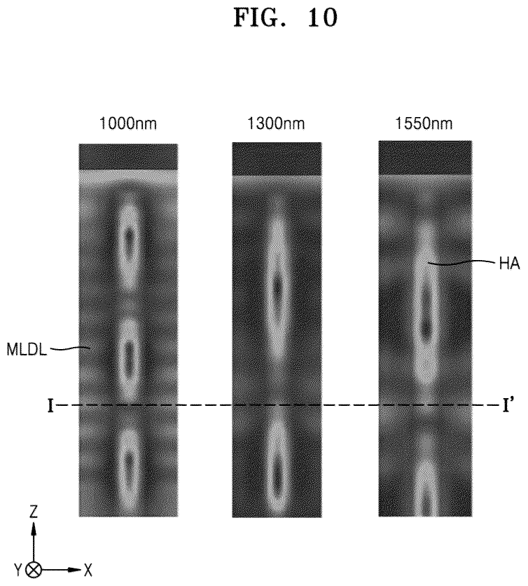

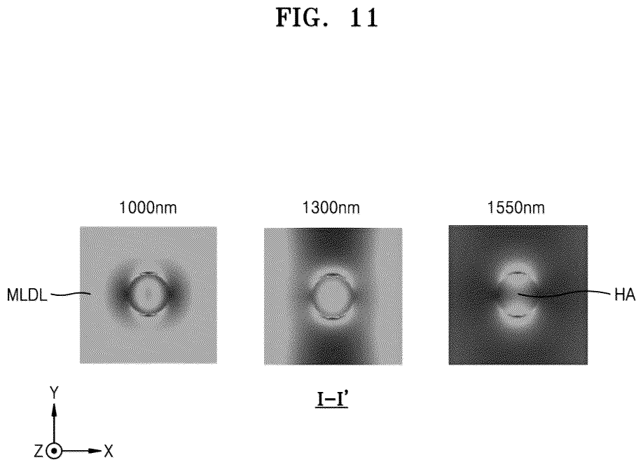

FIG. 8 is cross-sectional views each illustrating an inspection simulation result when a hole region of a semiconductor device, according to one or more embodiments, is filled with air. FIG. 9 is cross-sectional views each illustrating an inspection simulation result when a hole region of a semiconductor device according to one or more embodiments is filled with a material including carbon. FIG. 10 is cross-sectional views each illustrating an inspection simulation result when a hole region of a semiconductor device according to one or more embodiments is filled with amorphous silicon. FIG. 11 is cross-sectional views each illustrating an inspection simulation result for cross-sections in the vertical direction taken along line I-I′ of FIG. 10.

Referring to FIGS. 8 to 11, it may be seen that three simulation results having different wavelength bands of the light L are sequentially shown. In one or more embodiments, the leftmost simulation result is a case in which the wavelength band of the light Lis 1000 nm. In one or more embodiments, the intermediate simulation result is a case where the wavelength band of the light L is 1300 nm. In one or more embodiments, the rightmost simulation result is a case in which the wavelength band of the light L is 1550 nm.

FIG. 8 is a view in which the inside of the hole region HA is filled with air. In the case of FIG. 8, the refractive index of the molding layer MLDL is higher than that of air filled in the hole region HA. In the simulation results, it may be seen that only the region where the hole region HA and the molding layer MLDL are in contact with each other is more clearly measured. It may be seen that information about the inside of the hole region HA may not be accurately measured. For example, it may be seen that the light L does not mainly proceed inside the hole region HA, but crosses the molding layer MLDL and the hole region HA, or proceeds within the molding layer MLDL. It may be seen that almost the same results may be obtained even when the wavelength bands of light are 1000 nm, 1300 nm, and 1550 nm, respectively.

In FIG. 9, the inside of the hole region HA is filled with a material including carbon. In FIG. 9, a refractive index of the molding layer MLDL is higher than that of a material including carbon filled in the hole region HA. In the simulation results, similarly to FIG. 8, it may be seen that only the region where the hole region HA and the molding layer MLDL are in contact with each other is more clearly measured. It may be seen that information about the inside of the hole region HA may not be accurately measured. That is, it may be seen that the light does not mainly proceed inside the hole region HA, but crosses the molding layer MLDL and the hole region HA, or proceeds within the molding layer MLDL. It may be seen that almost the same results may be obtained even when the wavelength bands of light are 1000 nm, 1300 nm, and 1550 nm, respectively.

In FIG. 10, the inside of the hole region HA is filled with amorphous silicon (a-Si). In the case of FIG. 10, the refractive index of the amorphous silicon (a-Si) filled in the hole region HA is higher than the refractive index of the molding layer MLDL. In the simulation results, unlike FIGS. 8 and 9, it may be seen that light is mainly reflected inside the hole region HA. Therefore, it may be seen that information on the inside of the hole region HA may be more accurately measured than the information on the molding layer MLDL. It may be seen that almost the same results may be obtained even when the wavelength bands of light are 1000 nm, 1300 nm, and 1550 nm, respectively. Even when viewed from the vertical direction in FIG. 11, it may be seen that the measured results show that light propagates not only at the boundary between the hole region HA and the molding layer MLDL, but also inside the hole region HA.

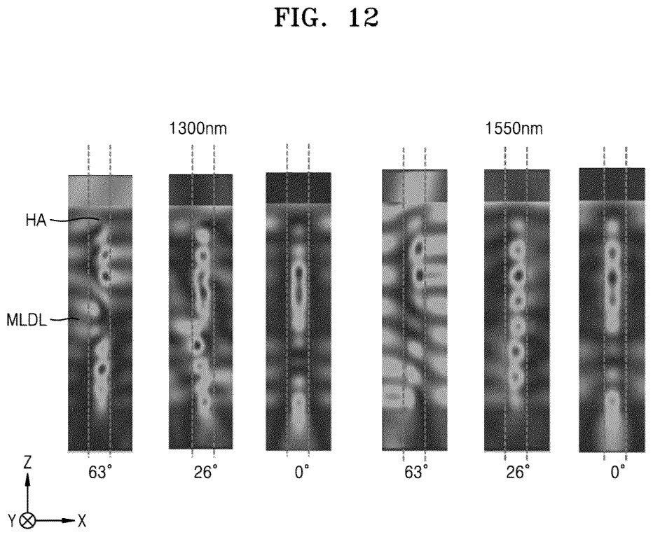

FIG. 12 is cross-sectional views each illustrating an inspection simulation result obtained while varying an angle of a light source when a hole region of a semiconductor device according to one or more embodiments is filled with amorphous silicon.

In FIG. 12, the inside of the hole region HA is filled with amorphous silicon (a-Si). The wavelength bands of light are 1300 nm and 1550 nm, and the simulation was conducted by setting the angle of the light source differently for each wavelength band. The simulation was conducted at an angle of the light source varying at 0, 26, and 63 degrees, respectively. In all six cases of combinations of the wavelength band and the angle of the light source, it may be seen that the main region in which light is measured coincides with the interior of the hole region HA. For example, it may be confirmed that light is completely or substantially reflected and proceeds inside the hole region HA rather than inside the molding layer MLDL. As long as the incident angle of light emitted from the light source is not greater than the magnitude of the critical angle θc determined by the refractive index of each of the amorphous silicon (a-Si) and the molding layer surrounding the outside of the hole region HA, it may be confirmed that the hole region HA may serve as a waveguide.

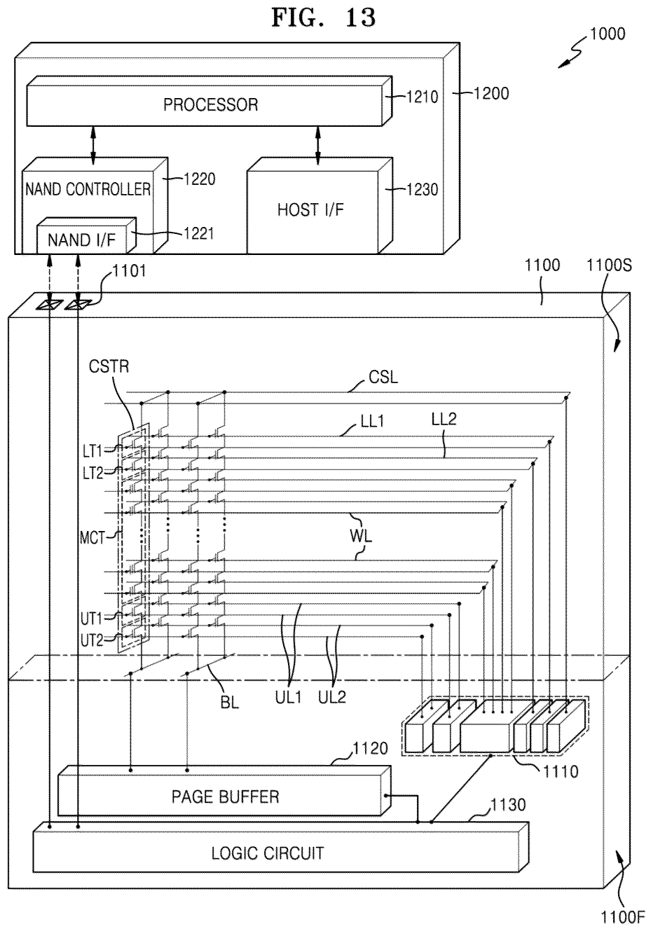

FIG. 13 is a perspective diagram schematically illustrating an electronic system including a semiconductor device according to one or more embodiments.

Referring to FIG. 13, the electronic system 1000 may include at least one memory device 1100 and a memory controller 1200 electrically connected to the at least one memory device 1100. The electronic system 1000 may be, for example, a solid state drive device (SSD), a universal serial bus (USB), a computing system, a medical device, or a communication device, which includes the at least one memory device 1100.

The at least one memory device 1100 may be an integrated circuit device including a nonvolatile memory device. For example, the at least one memory device 1100 may include the semiconductor device 10 described with reference to FIG. 3. The at least one memory device 1100 may include a first structure 1100F and a second structure 1100S on the first structure 1100F. The first structure 1100F may be a peripheral circuit structure. The peripheral circuit structure may include a row decoder 1110, a page buffer 1120, and a logic circuit 1130.

The second structure 1100S may be a cell array structure. The second structure 1100S may include a bit line BL, a common source line CSL, a plurality of word lines WL, first and second string selection lines UL1 and UL2, first and second ground selection lines LL1 and LL2, and a plurality of memory cell strings CSTR between the bit line BL and the common source line CSL. Gate electrodes and channel structures may form a plurality of memory cell strings CSTR.

In the second structure 1100S, each of the plurality of memory cell strings CSTR may include ground selection transistors LT1 and LT2 adjacent to the common source line CSL, string selection transistors UT1 and UT2 adjacent to the bit line BL, and a plurality of memory cell transistors MCT disposed between the ground selection transistors LT1 and LT2 and the string selection transistors UT1 and UT2. The number of the ground selection transistors LT1 and LT2 and the number of the string selection transistors UT1 and UT2 may be variously modified according to embodiments. One of the plurality of channel structures and one of the plurality of gate electrodes may form one of the plurality of transistors LT1, LT2, UT1, UT2, and MCT.

In embodiments, the plurality of ground selection lines LL1 and LL2 may be connected to the gate electrodes of the ground selection transistors LT1 and LT2, respectively. One word line WL may be connected to a gate electrode of the memory cell transistor MCT. The plurality of string selection lines UL1 and UL2 may be connected to the gate electrodes of the string selection transistors UT1 and UT2, respectively.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The at least one memory device 1100 may communicate with the memory controller 1200 through an external connection pad 1101 electrically connected to the logic circuit 1130. The external connection pad 1101 may be electrically connected to the logic circuit 1130.

The memory controller 1200 may include a processor 1210, a NAND controller 1220, and a host interface (HOST I/F) 1230. In some embodiments, the electronic system 1000 may include a plurality of memory devices 1100, and in this case, the memory controller 1200 may control the plurality of memory devices 1100.

The processor 1210 may control the overall operation of the electronic system 1000 including the memory controller 1200. The processor 1210 may operate according to a predetermined firmware and may access the memory device 1100 by controlling the NAND controller 1220. The NAND controller 1220 may include a NAND interface (NAND I/F) 1221 that processes communication with the memory device 1100. A control command for controlling the memory device 1100, data to be written in the plurality of memory cell transistors MCT of the memory device 1100, data to be read from the plurality of memory cell transistors MCT of the memory device 1100, and the like may be transmitted through the NAND interface 1221. The host interface 1230 may provide a communication function between the electronic system 1000 and an external host. When a control command is received from an external host through the host interface 1230, the processor 1210 may control the memory device 1100 in response to the control command.

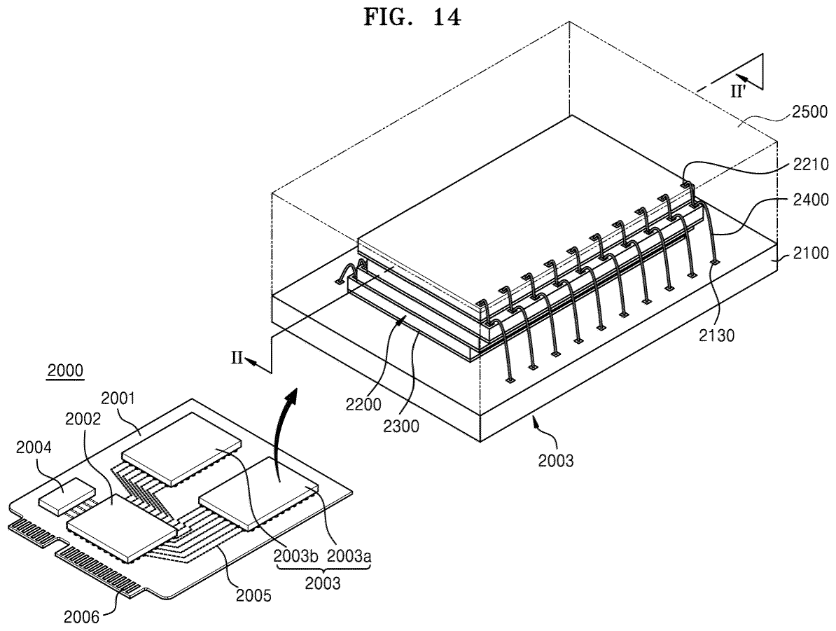

FIG. 14 is a perspective view schematically illustrating an electronic system including a semiconductor device according to one or more embodiments.

Referring to FIG. 14, an electronic system 2000 according to one or more embodiments may include a main board 2001, a memory controller 2002 mounted on the main board 2001, one or more semiconductor packages 2003, and a DRAM 2004. The semiconductor package 2003 and the DRAM 2004 may be connected to the memory controller 2002 by a plurality of wiring patterns 2005 formed on the main board 2001.

The main board 2001 may include a connector 2006 including a plurality of pins coupled to an external host. The number and arrangement of the plurality of pins in the connector 2006 may vary depending on the communication interface between the electronic system 2000 and the external host. In embodiments, the electronic system 2000 may communicate with an external host according to any one of interfaces such as Universal Serial Bus (USB), Peripheral Component Interconnect Express (PCI-Express), Serial Advanced Technology Attachment (SATA), and M-Phy for Universal Flash Storage (UFS). In embodiments, the electronic system 2000 may operate by power supplied from an external host through the connector 2006. The electronic system 2000 may further include a power management integrated circuit (PMIC) for distributing power supplied from the external host to the memory controller 2002 and the semiconductor package 2003.

The memory controller 2002 may write data in the semiconductor package 2003 or read data from the semiconductor package 2003, and may improve the operating speed of the electronic system 2000.

The DRAM 2004 may be a buffer memory for mitigating a speed difference between the semiconductor package 2003 that is a data storage space and an external host. The DRAM 2004 included in the electronic system 2000 may also operate as a kind of cache memory, and may provide a space for temporarily storing data in a control operation for the semiconductor package 2003. When the electronic system 2000 includes the DRAM 2004, the memory controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package board 2100, the plurality of semiconductor chips 2200 on the package board 2100, an adhesive layer 2300 disposed on the bottom surface of each of the plurality of semiconductor chips 2200, a connection structure 2400 electrically connecting the plurality of semiconductor chips 2200 to the package board 2100, and a molding layer 2500 covering the plurality of semiconductor chips 2200 and the connection structure 2400 on the package board 2100.

The package board 2100 may be a printed circuit board including a plurality of package upper pads 2130. Each of the plurality of semiconductor chips 2200 may include an input/output pad 2210. Each of the plurality of semiconductor chips 2200 may include the semiconductor device 10 described with reference to FIG. 3.

In embodiments, the connection structure 2400 may be a bonding wire electrically connecting the input/output pads 2210 to the package upper pads 2130. Therefore, in the first and second semiconductor packages 2003a and 2003b, the plurality of semiconductor chips 2200 may be electrically connected to each other in a bonding wire manner, and may be electrically connected to the package upper pads 2130 of the package board 2100. In embodiments, in the first and second semiconductor packages 2003a and 2003b, the plurality of semiconductor chips 2200 may be electrically connected to each other by a connection structure including a through silicon via (TSV) instead of a bonding wire type connection structure 2400.

In embodiments, the memory controller 2002 and the plurality of semiconductor chips 2200 may be included in a single package. In one or more embodiments, the memory controller 2002 and the plurality of semiconductor chips 2200 may be mounted on a separate interposer substrate different from the main board 2001, and the memory controller 2002 and the plurality of semiconductor chips 2200 may be connected to each other by wirings formed on the interposer substrate.

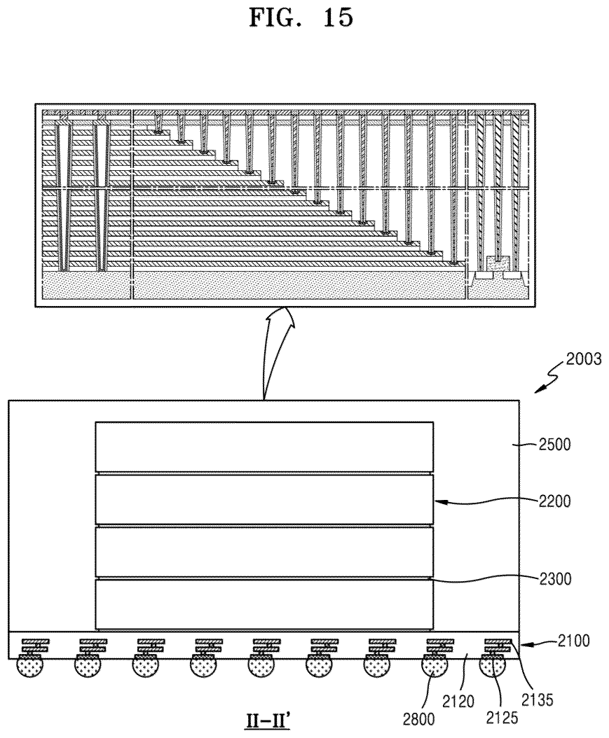

FIG. 15 is a cross-sectional view schematically illustrating a semiconductor package including a semiconductor device according to one or more embodiments.

Referring to FIG. 15, in the semiconductor package 2003, the package board 2100 may be a printed circuit board. The package board 2100 may include a package board body part 2120, a plurality of package upper pads 2130 (see FIG. 14) arranged on the top surface of the package board body part 2120, a plurality of lower pads 2125 disposed on the bottom surface of the package board body part 2120 or exposed through the bottom surface thereof, and a plurality of internal wires 2135 electrically connecting the plurality of package upper pads 2130 (see FIG. 14) with the plurality of lower pads 2125 within the package board body part 2120. As shown in FIG. 14, the plurality of package upper pads 2130 may be electrically connected to the plurality of connection structures 2400, respectively. The plurality of lower pads 2125 may be connected to the plurality of wiring patterns 2005 on the main board 2001 of the electronic system 2000 shown in FIG. 14 through a plurality of conductive bumps 2800. Each of the plurality of semiconductor chips 2200 may include the semiconductor device 10 described with reference to FIG. 3.

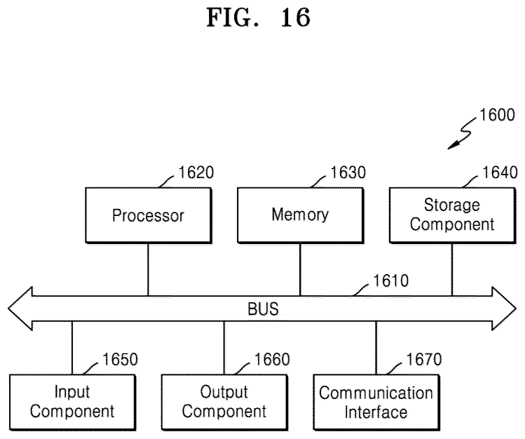

FIG. 16 is a block diagram of example components that include a processor. The device 1600 may include the above-mentioned processor or control unit. The device 1600 may perform the method S10 (FIG. 1). As shown in FIG. 16, the device 1600 may include a bus 1610, a processor 1620, a memory 1630, a storage component 1640, an input component 1650, an output component 1660, and a communication interface 1670.

The bus 1610 includes a component that permits communication among the components of the device 1600. The processor 1620 is implemented in hardware, firmware, or a combination of hardware and software. The processor 1620 is a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, the processor 1620 includes one or more processors capable of being programmed to perform a function. The memory 1630 includes a random access memory (RAM), a read only memory (ROM), and/or another type of dynamic or static storage device (e.g. a flash memory, a magnetic memory, and/or an optical memory) that stores information and/or instructions for use by the processor 1620.

The storage component 1640 stores information and/or software related to the operation and use of the device 1600. For example, the storage component 1640 may include a hard disk (e.g. a magnetic disk, an optical disk, a magneto-optic disk, and/or a solid state disk), a compact disc (CD), a digital versatile disc (DVD), a floppy disk, a cartridge, a magnetic tape, and/or another type of non-transitory computer-readable medium, along with a corresponding drive.

The input component 1650 includes a component that permits the device 1600 to receive information, such as via user input (e.g. a touch screen display, a keyboard, a keypad, a mouse, a button, a switch, and/or a microphone). Additionally, or alternatively, the input component 1650 may include a sensor for sensing information (e.g. a global positioning system (GPS) component, an accelerometer, a gyroscope, and/or an actuator). The output component 1660 includes a component that provides output information from the device 1600 (e.g. a display, a speaker, and/or one or more light-emitting diodes (LEDs)).

The communication interface 1670 includes a transceiver-like component (e.g., a transceiver and/or a separate receiver and transmitter) that enables the device 1600 to communicate with other devices, such as via a wired connection, a wireless connection, or a combination of wired and wireless connections. The communication interface 1670 may permit the device 1600 to receive information from another device and/or provide information to another device. For example, the communication interface 1670 may include an Ethernet interface, an optical interface, a coaxial interface, an infrared interface, a radio frequency (RF) interface, a universal serial bus (USB) interface, a Wi-Fi interface, a cellular network interface, or the like.

The device 1600 may perform one or more processes described herein. The device 1600 may perform these processes in response to the processor 1620 executing software instructions stored by a non-transitory computer-readable medium, such as the memory 1630 and/or the storage component 1640. A computer-readable medium is defined herein as a non-transitory memory device. A memory device includes memory space within a single physical storage device or memory space spread across multiple physical storage devices.

Software instructions may be read into the memory 1630 and/or the storage component 1640 from another computer-readable medium or from another device via the communication interface 1670. When executed, software instructions stored in the memory 1630 and/or the storage component 1640 may cause the processor 1620 to perform one or more processes described herein. Additionally, or alternatively, hardwired circuitry may be used in place of or in combination with software instructions to perform one or more processes described herein. Thus, implementations described herein are not limited to any specific combination of hardware circuitry and software.

The number and arrangement of components shown in FIG. 16 are provided as an example. In practice, the device 1600 may include additional components, fewer components, different components, or differently arranged components than those shown in FIG. 16. Additionally, or alternatively, a set of components (e.g. one or more components) of the device 1600 may perform one or more functions described as being performed by another set of components of the device 1600.

While the embodiments of the present disclosure have been particularly shown and described with reference to embodiments thereof, it will be understood that various changes in form and details may be made therein without departing from the spirit and scope of the following claims.

What is claimed is:

1. A semiconductor device inspection method comprising:
selecting, for a semiconductor device including at least one layer, a target layer on which inspection and measurement are to be performed;
selecting a material to fill a hole region formed inside the semiconductor device;
conducting a simulation for an optical inspection and a measurement for the semiconductor device;
selecting, based on the simulation, a wavelength band of light for the optical inspection and the measurement; and
detecting, through the light at the selected wavelength, a lower portion of the semiconductor device and a defect of the semiconductor device, wherein
a refractive index of the material filling the inside of the hole region is greater than a refractive index of a molding layer surrounding the outside of the hole region.

2. The semiconductor device inspection method of claim 1, wherein the conducting of the simulation comprises rotating a light source that emits the light to a plurality of angles and performing the optical inspection and the measurement for each angle of the plurality of angles.

3. The semiconductor device inspection method of claim 1, wherein a magnitude of an angle of the optical inspection and the measurement is less than a magnitude of a critical angle determined by a refractive index of each of the material to fill the hole region and the molding layer surrounding the outside of the hole region.

4. The semiconductor device inspection method of claim 1, wherein a light source emitting the light is a short wavelength light source or a broadband light source.

5. The semiconductor device inspection method of claim 1, wherein the material filling the hole region comprises amorphous silicon (a-Si).

6. The semiconductor device inspection method of claim 1, wherein the light is reflected inside the hole region and travels to the bottom of the hole region.

7. The semiconductor device inspection method of claim 1, wherein, a diameter of the hole region is less than a wavelength of the light.

8. The semiconductor device inspection method of claim 1, wherein a focus of a light source emitting the light is located in a bottom region of the hole region, and an inside of the hole region.

9. The semiconductor device inspection method of claim 1, wherein a plurality of hole regions are formed inside the semiconductor device, and one or more depths of the plurality of hole regions differ from each other.

10. The semiconductor device inspection method of claim 1, wherein a wavelength band of the light ranges from about 1000 nanometers to about 1550 nanometers.

11. A semiconductor device inspection method comprising:
selecting an inspection and measurement target layer of a semiconductor device including a plurality of layers;
selecting a material to be deposited in a hole region formed in the semiconductor device;
conducting a simulation for an optical inspection and a measurement for the semiconductor device;
selecting, based on the simulation, a wavelength band of light emitted from a light source for performing the inspection and measurement; and
analyzing data corresponding to light incident on the hole region at the selected wavelength to detect a lower portion of the semiconductor device and a defect of the semiconductor device,
wherein a refractive index of the material filling the inside of the hole region is greater than a refractive index of a molding layer surrounding the outside of the hole region,
wherein the conducting of the simulation includes performing the optical inspection and measurement for each angle, and
wherein an angle of the light source with respect to the hole region is determined according to data for light incident on the hole region.

12. The semiconductor device inspection method of claim 11, wherein an angle of the light source with respect to the hole region is less than a critical angle determined by a refractive index of each of a material filling the hole region and the molding layer surrounding the outside of the hole region.

13. The semiconductor device inspection method of claim 11, wherein the hole region has a tapered shape in which a cross-sectional area thereof in a direction perpendicular to a direction of a depth of the hole region gradually decreases.

14. The semiconductor device inspection method of claim 11, wherein a light source emitting the light is a short wavelength light source or a broadband light source, and the light is emitted in a plurality of modes.

15. The semiconductor device inspection method of claim 11, wherein the molding layer comprises one of an oxide layer, a nitride layer, and a combination thereof, and the material filling the hole region is amorphous silicon (a-Si).

16. The semiconductor device inspection method of claim 11, wherein the light has a wavelength greater than a diameter of the hole region, and the light is reflected inside the hole region and travels to the bottom of the hole region.

17. The semiconductor device inspection method of claim 11,
wherein a plurality of hole regions are formed inside the semiconductor device,
wherein one or more depths of the plurality of hole regions differ from each other, and
wherein a focus of a light source emitting the light is located in a bottom region of the hole region and an inside the hole region.

18. The semiconductor device inspection method of claim 11, wherein a wavelength band of the light ranges from about 1000 nanometers to about 1550 nanometers.

19. A semiconductor device inspection method of inspecting a semiconductor device including a plurality of hole regions, each hole region having a high aspect ratio contact (HARC), the method comprising:
selecting an inspection and measurement target layer of the semiconductor device, wherein one or more depths of the plurality of hole regions differ from each other;
selecting a material to be deposited in a hole region formed in the semiconductor device;
conducting a simulation for an optical inspection and a measurement for the semiconductor device;
selecting, based on the simulation, a wavelength band of light emitted from a light source for performing the inspection and measurement; and
analyzing data corresponding to light incident on the hole region at the selected wavelength to detect a lower portion of the semiconductor device and a defect of the semiconductor device,
wherein a refractive index of the material filling the inside of the hole region is greater than a refractive index of a molding layer surrounding the outside of the hole region,
wherein the conducting of the simulation includes performing the optical inspection and measurement for each angle, by a measurement unit,
wherein an angle of the light source with respect to the hole region is less than a critical angle determined by a refractive index of each of a material filling the hole region and a molding layer surrounding the outside of the hole region,
wherein the molding layer comprises one of an oxide layer, a nitride layer, and a combination thereof, and
wherein the material filling the hole region comprises amorphous silicon (a-Si).

20. The semiconductor device inspection method of claim 19, wherein the light is emitted from a short wavelength light source or a broadband light source, wherein the light is located in the bottom region of the hole region and inside the hole region,
wherein the light is emitted in a plurality of modes,
wherein the light has a wavelength greater than a diameter of the hole region, and
the light is reflected inside the hole region and travels to the bottom of the hole region.
